(19) United States
(12) Patent Application Publication
(10) Pub. No.: US 2026/0343916 A1
(43) Pub. Date: Oct. 29, 2026

(54) SEMICONDUCTOR DEVICE, METHOD FOR CONTROLLING SEMICONDUCTOR DEVICE, AND METHOD OF MANUFACTURING SEMICONDUCTOR DEVICE

(71) Applicants: Mitsubishi Electric Corporation, Tokyo (JP); Nisshinbo Micro Devices Inc., Tokyo (JP)

(72) Inventors: Tomohiro TAMAKI, Tokyo (JP); Makoto HASHIMOTO, Tokyo (JP); Yohei SUDO, Tokyo (JP); Tadayoshi DEGUCHI, Tokyo (JP); Mitsuhisa KAWASE, Tokyo (JP)

(73) Assignees: Mitsubishi Electric Corporation, Tokyo (JP); Nisshinbo Micro Devices Inc., Tokyo (JP)

(21) Appl. No.: 19/107,053

(22) PCT Filed: Sep. 5, 2022
(86) PCT No.: PCT/JP2022/033226

§ 371 Date: Feb. 27, 2025

(51) Int. Cl. H10D 12/00; H10D 12/01; H10D 62/10; H10D 62/60

(52) U.S. Cl. CPC H10D 12/481; H10D 12/032; H10D 12/038; H10D 12/441; H10D 62/107; H10D 62/124; H10D 62/60

(57) ABSTRACT

A semiconductor device according to the present disclosure includes: a drift layer including a first pillar region and a second pillar region that are alternately disposed; a base region; a gate insulating film; a gate electrode; a carrier stored region; and an emitter region, wherein a lower end of the second pillar region is located closer to the side of the second main surface than a lower end of the first pillar region, and wp3>wp2 and wp1>wp2 hold, where wp1 denotes a width of an upper end of the second pillar region that is an end portion on the side of the first main surface, wp2 denotes a width of the second pillar region at a same position as a lower end of the first pillar region, and wp3 denotes a width of the lower end of the second pillar region.

### BACKGROUND OF THE INVENTION

### Field of the Invention

The present disclosure relates to a semiconductor device, a method for controlling the semiconductor device, and a method of manufacturing the semiconductor device.

### Description of the Background Art

A super-junction structure in which n-type pillar regions and p-type pillar regions are alternately disposed in a plan view is a structure mainly used for a drift layer of a power metal-oxide-semiconductor field-effect transistor (MOSFET). Narrowing pitches of the n-type pillar regions and the p-type pillar regions can increase the density of the n-type pillar regions (reduce the resistance of the n-type pillar regions). The power MOSFETs using the super-junction structure can obtain, with the same breakdown voltage, lower ON voltages than those of conventional power MOSFETs (power MOSFETs without using the super junction structure).

Super-junction insulated-gate bipolar transistors (IGBTs), which are obtained by applying the super-junction structure to IGBTs, exert the injection enhanced (IE) effect using holes injected from p-type collector layers on the back surfaces as in the conventional IGBTs (IGBTs without using the super junction structure) to enhance the conductivity modulation. This place expectations on additional reduction in ON voltage.

What is disclosed is a technology of restricting the movement of the holes injected from a p-type collector layer on the back surface by providing an n-type carrier stored region between an n-type drift region and a p-type base region in a conventional IGBT to enable the reduction in ON voltage (e.g., see Patent Document 1).

What is also disclosed is to enable improvement of the trade-off relationship between the collector-to-emitter ON voltage Vce (sat) and the turn off loss Eoff in a super-junction IGBT more than those of conventional IGBTs (e.g., see Patent Document 2).

What is also disclosed is a super-junction structure in which n-type pillar regions and p-type pillar regions are vertically formed in a depth direction (e.g., see Non-Patent Document 1).

### PRIOR ART DOCUMENT

### Patent Document

Patent Document 1: Japanese Patent No. 3288218

Patent Document 2: Japanese Unexamined Patent Application Publication No. 2009-525610

### Non-Patent Document

Non-Patent Document 1: T. Tamaki, “Vertical Charge Imbalance Effect on 600 V-class Trench-Filling Superjunction Power MOSFETs”, the 23rd International Symposium on Power Semiconductor Devices & IC's, May 23 to 26, 2011, p. 308-311

### SUMMARY

### Problem to be Solved by the Invention

Patent Documents 1 and 2 and Non-Patent Document 1 fail to disclose the super-junction structure that can make reduction in ON voltage compatible with robustness of breakdown voltage. For example, in Patent Document 2, p-type pillar regions are electrically connected to a p-type base region, and holes injected from the back surface in the ON state are ejected to an emitter terminal through the p-type pillar regions and the p-type base region. Thus, reduction in ON voltage requires increasing the density of n-type pillar regions by narrowing pitches of disposing the n-type pillar regions and the p-type pillar regions. However, narrowing the pitches is limited by manufacturing technology. Furthermore, increasing the density of the n-type pillar regions creates a conducting state that causes electrons to disproportionately flow through the n-type pillar regions and causes holes to disproportionately flow through the p-type pillar regions. Thus, there is a limitation in reducing the ON voltage.

Since a structure in which the n-type pillar regions and the p-type pillar regions are vertically formed in the depth direction as in Non-Patent Document 1 exhibits a high sensitivity of an element breakdown voltage to the density of pillar regions, this causes an inconvenience of significantly damaging the robustness of breakdown voltage to manufacturing variations.

The present disclosure has been conceived to solve such problems, and has an object of providing a semiconductor device with a super-junction structure that can make reduction in ON voltage compatible with robustness of breakdown voltage, a method for controlling the semiconductor device, and a method of manufacturing the semiconductor device.

### Means to Solve the Problem

To solve the problems, a semiconductor device according to the present disclosure has a first main surface, and a second main surface facing the first main surface, and includes: a drift layer including a first pillar region of a first conductivity type and a second pillar region of a second conductivity type, the first pillar region and the second pillar region being alternately disposed in a direction parallel to the first main surface and the second main surface; a base region of the second conductivity type, the base region being selectively disposed in the drift layer on a side of the first main surface; a gate insulating film disposed in contact with the base region; a gate electrode disposed to face the base region through the gate insulating film; a carrier stored region of the first conductivity type, the carrier stored region being disposed between the base region and the second pillar region; and an emitter region of the first conductivity type, the emitter region being selectively disposed in a surface layer of the base region on the side of the first main surface, wherein a lower end of the second pillar region that is an end portion on a side of the second main surface is located closer to the side of the second main surface than a lower end of the first pillar region that is an end portion on the side of the second main surface, and wp3>wp2 and wp1>wp2 hold, where wp1 denotes a width of an upper end of the second pillar region that is an end portion on the side of the first main surface, wp2 denotes a width of the second pillar region at a same position as a lower end of the first pillar region, and wp3 denotes a width of the lower end of the second pillar region.

### Effects of the Invention

The present disclosure can make reduction in ON voltage compatible with robustness of breakdown voltage.

The object, features, aspects, and advantages of this disclosure will become more apparent from the following detailed description and the accompanying drawings.

### BRIEF DESCRIPTION OF THE DRAWINGS

FIG. 1 is a cross-sectional view illustrating an example structure of a semiconductor device according to Embodiment 1.

FIG. 2 illustrates a relationship between a ratio of a quantity of impurities in a p-type pillar region to a quantity of impurities in an n-type pillar region and the breakdown voltage of a semiconductor device.

FIG. 3 illustrates a relationship between a ratio of a quantity of impurities in a p-type pillar region to a quantity of impurities in an n-type pillar region and the breakdown voltage of a semiconductor device.

FIG. 4 illustrates a relationship between a ratio of a quantity of impurities in a p-type pillar region to a quantity of impurities in an n-type pillar region and the breakdown voltage of a semiconductor device.

FIG. 5 illustrates a relationship between a ratio of a quantity of impurities in a p-type pillar region to a quantity of impurities in an n-type pillar region and the breakdown voltage of a semiconductor device.

FIG. 6 is a graph illustrating example electric field intensities in a direction from the first main surface to the second main surface of the semiconductor device.

FIG. 7 is a cross-sectional view illustrating an example process of manufacturing the semiconductor device according to Embodiment 1.

FIG. 8 is a cross-sectional view illustrating an example process of manufacturing the semiconductor device according to Embodiment 1.

FIG. 9 is a cross-sectional view illustrating an example process of manufacturing the semiconductor device according to Embodiment 1.

FIG. 10 is a cross-sectional view illustrating an example process of manufacturing the semiconductor device according to Embodiment 1.

FIG. 11 is a cross-sectional view illustrating an example process of manufacturing the semiconductor device according to Embodiment 1.

FIG. 12 is a cross-sectional view illustrating an example process of manufacturing the semiconductor device according to Embodiment 1.

FIG. 13 is a cross-sectional view illustrating an example process of manufacturing the semiconductor device according to Embodiment 1.

FIG. 14 is a cross-sectional view illustrating an example process of manufacturing the semiconductor device according to Embodiment 1.

FIG. 15 is a cross-sectional view illustrating an example process of manufacturing the semiconductor device according to Embodiment 1.

FIG. 16 is a cross-sectional view illustrating an example process of manufacturing the semiconductor device according to Embodiment 1.

FIG. 17 is a cross-sectional view illustrating an example process of manufacturing the semiconductor device according to Embodiment 1.

FIG. 18 is a cross-sectional view illustrating an example structure of a semiconductor device according to a modification of Embodiment 1.

FIG. 19 is a cross-sectional view illustrating an example structure of a semiconductor device according to Embodiment 2.

FIG. 20 is a cross-sectional view illustrating an example structure of a semiconductor device according to Modification 1 of Embodiment 2.

FIG. 21 is a cross-sectional view illustrating an example structure of a semiconductor device according to Modification 2 of Embodiment 2.

FIG. 22 is a cross-sectional view illustrating an example structure of a semiconductor device according to Embodiment 3.

FIG. 23 is a cross-sectional view illustrating an example process of manufacturing the semiconductor device according to Embodiment 3.

FIG. 24 is a cross-sectional view illustrating an example process of manufacturing the semiconductor device according to Embodiment 3.

FIG. 25 is a cross-sectional view illustrating an example process of manufacturing the semiconductor device according to Embodiment 3.

FIG. 26 is a cross-sectional view illustrating an example process of manufacturing the semiconductor device according to Embodiment 3.

FIG. 27 is a cross-sectional view illustrating an example structure of a semiconductor device according to a modification of Embodiment 3.

FIG. 28 is a plan view illustrating an example top layout of a semiconductor device according to Embodiment 4.

FIG. 29 is a cross-sectional view of A1-A2 in FIG. 28.

FIG. 30 is a graph illustrating an example timing chart of the first gate voltage and the second gate voltage for driving the semiconductor device according to Embodiment 4.

FIG. 31 is a graph illustrating an example delay-time dependence of the second gate voltage on the surge voltage and the turn off loss in the semiconductor device according to Embodiment 4.

FIG. 32 is a cross-sectional view illustrating an example structure of a semiconductor device according to a modification of Embodiment 4.

### DESCRIPTION OF THE PREFERRED EMBODIMENTS

Embodiments of the present disclosure will be described with reference to the drawings. In Embodiments below, the first conductivity type is n-type, and the second conductivity type is p-type. The same numbers are attached to the same portions in the drawings. Not a termination structure in a surrounding region of a device (a semiconductor device) but a cross-sectional structure of a unit cell is illustrated. A semiconductor substrate to be used in the device may be the one manufactured appropriately using the substrate manufacturing technology necessary for manufacturing the device without depending on a method of manufacturing the substrate, such as a wafer manufactured in a magnetic field applied Czochralski (MCZ) method, a wafer manufactured in a floating zone (FZ) method, or an epitaxial substrate manufactured in a Czochralski (CZ) method.

The device may be a vertical metal-oxide-semiconductor field-effect transistor (MOSFET) using an n-type drain layer instead of a p-type collector layer on the back surface, or an n-type collector layer may be partially patterned together with the p-type collector layer. Alternatively, the device may be a reverse-conducting IGBT which includes both of a MOSFET region and a diode region on the front surface and in which a p-type collector region is disposed on the back surface of a semiconductor substrate immediately under the MOSFET region and an n-type cathode region is disposed on the back surface of the semiconductor substrate immediately under the diode region.

### Embodiment 1

### Structure of Semiconductor Device According to Embodiment 1

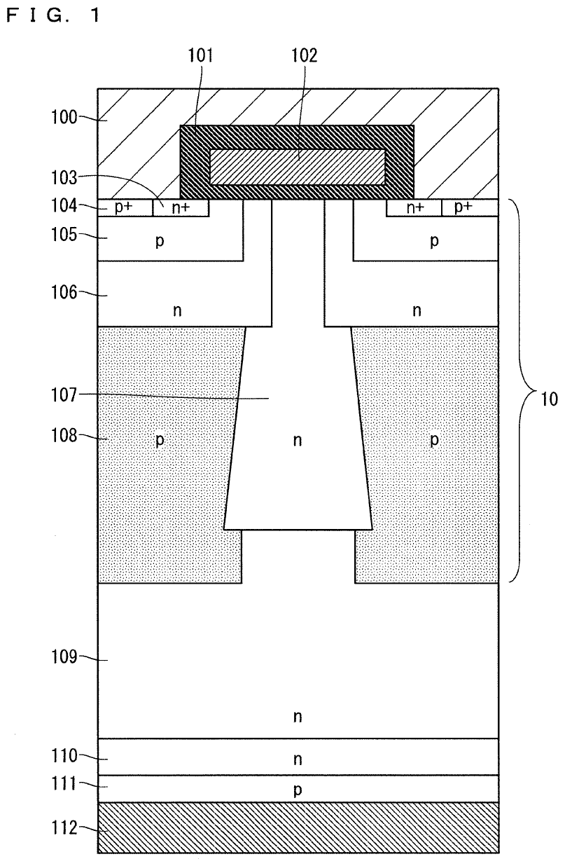

FIG. 1 is a cross-sectional view illustrating an example structure of a semiconductor device according to Embodiment 1. The semiconductor device in FIG. 1 is a planar-gate super-junction IGBT element manufactured using a silicon-based semiconductor substrate. Although a semiconductor device of which emitter-to-collector breakdown voltage is approximately 1200 bolt is specifically described hereinafter as an example, the following description is applicable to super-junction IGBT elements with other breakdown voltage values or semiconductor devices with other super-junction structures.

The semiconductor device in FIG. 1 has a first main surface, and a second main surface facing the first main surface. The first main surface is a surface on the upper side of the paper in FIG. 1, and corresponds to the front surface of the semiconductor device. The second main surface is a surface on the lower side of the paper in FIG. 1, and corresponds to the back surface of the semiconductor device.

A drift layer 10 includes n-type pillar regions 107 (first pillar regions of the first conductivity type) and p-type pillar regions 108 (second pillar regions of the second conductivity type) which are alternately disposed in a direction parallel to the first main surface and the second main surface. P-type base regions 105 are selectively disposed in the drift layer 10 on a side of the first main surface. N-type emitter regions 103 and p-type body contact regions 104 are selectively disposed in a surface layer of the p-type base regions 105 on the side of the first main surface. An n-type carrier stored region (CS region) 106 is disposed between the p-type base regions 105 and the p-type pillar regions 108. A gate insulating film 101 is disposed in contact with the p-type base regions 105. A gate electrode 102 is disposed to face the p-type base regions 105 through the gate insulating film 101. A lower end of the p-type pillar region 108 that is an end portion on a side of the second main surface is located closer to the side of the second main surface than a lower end of the n-type pillar region 107 that is an end portion on the side of the second main surface. Assuming that wp1 denotes a width of an upper end of the p-type pillar region 108 that is an end portion on the side of the first main surface, wp2 denotes a width of the p-type pillar region 108 at the same position (the same depth position) as the lower end of the n-type pillar region 107, and wp3 denotes a width of the lower end of the p-type pillar region 108, wp3>wp2 and wp1>wp2 hold.

An n-type bottom layer 109 is disposed on the side of the second main surface with respect to the drift layer 10. An n-type buffer layer 110 is disposed on the side of the second main surface with respect to the n-type bottom layer 109. A p-type collector layer 111 is disposed on the side of the second main surface with respect to the n-type buffer layer 110. A collector electrode 112 is disposed on the side of the second main surface with respect to the p-type collector layer 111.

A plurality of gate electrodes 102 arranged in stripes are disposed above the n-type pillar regions 107. Arranging the gate electrodes 102 in stripes in a depth direction of the paper (a vertical direction of the paper) in FIG. 1 similarly to the p-type pillar regions 108 forms a MOSFET with a planar gate structure.

Although FIG. 1 exemplifies a structure in which the single gate electrode 102 is disposed above the single n-type pillar region 107 and pitches of the n-type pillar region 107 and the gate electrode 102 in the width direction are identical, widths of the n-type pillar region 107 and the gate electrode 102 in the width direction may be different.

### Effects of Semiconductor Device According to Embodiment 1

Next, effects of the semiconductor device according to Embodiment 1 will be described.

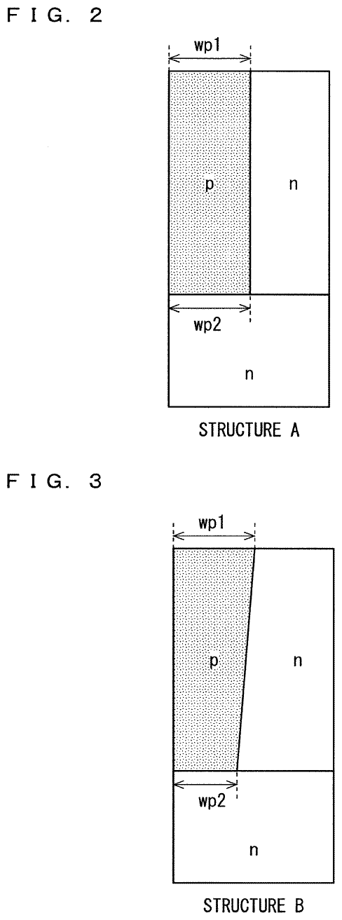

FIGS. 2 to 5 illustrate a relationship between a ratio of a quantity of impurities in a p-type pillar region to a quantity of impurities in an n-type pillar region and the breakdown voltage of a semiconductor device. In FIG. 5, the horizontal axis indicates the ratio (Qp/Qn) of the quantity of impurities in the p-type pillar region (Qp) to the quantity of impurities in the n-type pillar region (Qn), and the vertical axis indicates the breakdown voltage of the semiconductor device. Structures A to C in FIGS. 2 to 4 are super-junction structures. The structures A and B are super-junction structures of semiconductor devices according to comparative examples, and the structure C is a super-junction structure of the semiconductor device according to Embodiment 1. FIG. 5 illustrates a simulation result on the impact of the ratio of the impurities in each of the structures A to C in FIGS. 2 to 4 on the breakdown voltage.

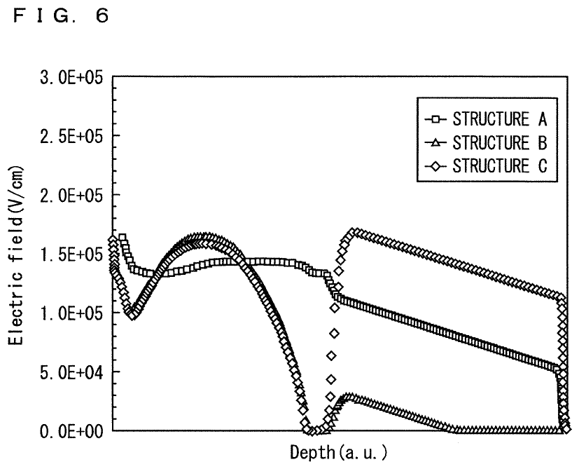

FIG. 6 is a graph illustrating example electric field intensities in a direction (a depth direction) from the first main surface to the second main surface of the semiconductor device. The structures A to C in FIG. 6 correspond to the structures A to C in FIGS. 2 to 5.

Operations of the semiconductor devices according to the comparative examples will be described. As illustrated in FIGS. 2 and 3, each of the semiconductor devices according to the comparative examples is a semiconductor device including a drift layer including an n-type pillar region and a p-type pillar region which makes up a super-junction structure (the structure A or B).

Depletion layers extend from a p-n junction interface between the p-type pillar region and the n-type pillar region to the p-type pillar region and the n-type pillar region by applying a voltage between a collector electrode as a positive electrode and an emitter electrode as a negative electrode. Here, setting the pitch spacing or impurity concentrations of the p-type pillar region and the n-type pillar region such that the depletion layers extending from the adjacent pillar regions can punch through each other can ensure the breakdown voltage.

The breakdown voltage of a semiconductor device depends on a ratio of impurity quantities in a drift layer. When the quantity of impurities in the n-type pillar region (Qn) is equal to the quantity of impurities in the p-type pillar region (Qp), that is, Qn=Qp, the extension of the depletion layers which corresponds to a voltage is maximized, and the breakdown voltage becomes the largest. In contrast, when one of the quantities of impurities is larger due to variations in manufacturing processes, that is, Qn>Qp or Qn<Qp, the depletion layers do not sufficiently extend, and the breakdown voltage decreases.

Furthermore, the sensitivity of a ratio of impurity quantities in a drift layer to a breakdown voltage of a semiconductor device is changed according to the shape of a pillar region. For example, when an upper end width and a lower end width (a width of a bottom) of a p-type pillar region are equal and the p-type pillar region is formed in a vertical direction, the sensitivity of the impact of changes in a ratio of impurity quantities in the pillar region on the breakdown voltage is increased. When Qn=Qp in which the breakdown voltage becomes the largest, the space charge density in the drift layer becomes almost zero, the electric field intensity distribution in the depth direction becomes flat, and the breakdown voltage is maximized. Here, a state where the quantity of impurities in the n-type pillar region (Qn) is equal to the quantity of impurities in the p-type pillar region (Qp) and the balance in charge quantity is achieved will be referred to as a charge balanced state.

In contrast, a state with a charge imbalance where one of the quantity of impurities in the n-type pillar region (Qn) or the quantity of impurities in the p-type pillar region (Qp) is larger will be referred to as a charge imbalance state. When Qn>Qp, a voltage applied to the drift layer at a positive space charge density is maintained. When Qn<Qp, a voltage applied to the drift layer at a negative space charge density is maintained. Here, the electric field intensity distribution in the drift layer has an inclination corresponding to a redundant charge quantity ΔQ (ΔQ=Qp−Qn) in the direction from the first main surface to the second main surface. Thus, the breakdown voltage in the charge imbalance state is lower than the breakdown voltage in the charge balanced state.

For example, as disclosed in Non-Patent Document 1, reduction in the breakdown voltage using the redundant charge quantity in the drift layer can be suppressed by forming a p-type pillar region of which lower end width is smaller than an upper end width thereof and which has a forward-tapered shape from the first main surface to the second main surface. This method allows the electric field distribution to have its electric field peak at a depth in the vicinity of almost the center of the drift layer in the charge balanced state (Qn=Qp), by not making the redundant charge quantity in the drift layer not uniform but reducing the redundant charge quantity in the drift layer in the direction from the first main surface to the second main surface to have a nonuniform redundant charge quantity. Here, the position of the electric field peak when Qn >Qp is shifted to a shallow portion (toward the first main surface), whereas the position of the electric field peak when Qn<Qp is shifted to a deep portion (toward the second main surface). Thus, the shape of the electric field intensity distribution even in the charge imbalance state does not significantly vary from that in the charge balanced state (no significant variation as in a p-type pillar region with a vertical shape). Consequently, the sensitivity of the ratio of impurity quantities in the drift layer to the breakdown voltage can be reduced.

Advantages of reducing the sensitivity of the ratio of impurity quantities in the drift layer to the breakdown voltage of the semiconductor device and improving the breakdown voltage of the semiconductor device as described above are applicable to super-junction MOSFET elements. In each of the super-junction MOSFET elements, a carrier stored region functioning as a current spreading layer can reduce the JFET resistance occurring between p-type base regions. Since the resistance component in a bottom layer even in the super-junction MOSFET element cannot be reduced, it is difficult to sufficiently reduce the ON resistance. Thus, forming an n-type buffer region and a p-type collector region on a side of a second main surface enables bipolar operations, and then forming a carrier stored region can further reduce the ON resistance.

Rendering a gate electrode conductive by applying a positive voltage higher than or equal to a threshold voltage of a MOS to the gate electrode forms an inversion layer in a surface of a p-type base region immediately under the gate electrode. Then, electrons are injected from an emitter electrode to a drift layer through an n-type emitter region and the inversion layer. The electrons injected into the drift layer are drifted by the electric field in the second main surface direction, and move to the collector electrode through the n-type buffer layer and the p-type collector layer. The electrons moved from the first main surface reduce a potential of the n-type buffer layer. Thus, a built-in potential of a p-n junction on the side of the second main surface decreases, and holes are injected from the p-type collector layer. Here, when the concentration of the holes injected from the p-type collector layer is higher than those of an n-type bottom layer and the drift layer, conductivity modulation occurs, so that the ON resistance can be reduced.

As illustrated in FIG. 5, however, the breakdown voltage value of the semiconductor device using the p-type pillar region with the forward-tapered shape (the structure B in FIG. 3) is lower than that of the semiconductor device using the p-type pillar region with the vertical shape (the structure A in FIG. 2) even in the charge balanced state (Qn=Qp). This is because the semiconductor device using the p-type pillar region with the vertical shape has an almost flat electric field intensity distribution in the depth direction, whereas the semiconductor device using the p-type pillar region with the forward-tapered shape has one peak in the drift layer in an electric field intensity distribution in the depth direction and the electric field intensity of each of an upper portion and the vicinity of a bottom of the p-type pillar region decreases, as illustrated in FIG. 6.

When the upper end of the p-type pillar region is connected to the p-type base region, the holes injected from the p-type collector layer to the n-type buffer layer and the n-type bottom layer in a conducting state are ejected to an emitter electrode as they are through the p-type pillar region and the p-type base region. This weakens the effect of the conductivity modulation in the drift layer on the side of the first main surface, and increases the ON voltage.

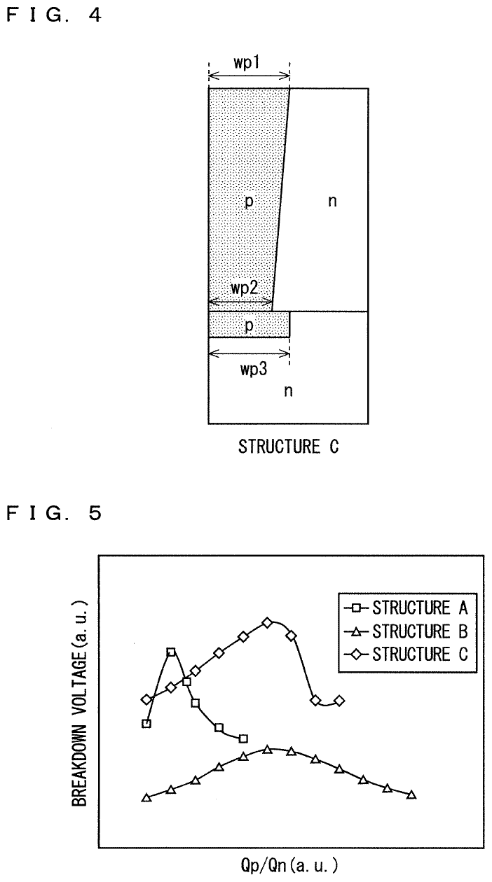

Thus, increasing the upper end width (wp1) of the p-type pillar region 108 more than the width (wp2) of the p-type pillar region 108 at the same depth position as the lower end of the n-type pillar region 107 (wp1>wp2) in the semiconductor device according to Embodiment 1 (the structure C in FIG. 4) exerts the effect of reducing the sensitivity of the ratio of impurity quantities in the drift layer 10 to the breakdown voltage. Furthermore, disposing the n-type bottom layer 109 under the drift layer 10, disposing the lower end of the p-type pillar region 108 closer to the side of the second main surface than the n-type pillar region 107, and increasing the maximum width (wp3) of the bottom of the p-type pillar region 108 in the n-type bottom layer 109 more than wp2 (wp3>wp2) can increase the electric field intensity in the vicinity of the bottom of the p-type pillar region 108, and improve the breakdown voltage. Furthermore, forming the n-type carrier stored region 106 between the upper ends of the p-type pillar regions 108 and the p-type base regions 105 exerts the effect of storing holes (or the IE effect), using the n-type carrier stored region 106 as a potential barrier of the holes injected from the p-type collector layer 111. Thus, the ON resistance can be reduced.

As illustrated in FIG. 1, the n-type carrier stored region 106 is separated immediately under the center of the gate electrode 102 (at a position corresponding to the center of the gate electrode 102) in the semiconductor device adopting the planar gate structure. Separating the n-type carrier stored region 106 immediately under the center of the gate electrode 102 can suppress an increase in the electric field at a junction interface between the p-type base regions 105 and the n-type carrier stored region 106, and obtain a desired breakdown voltage. Even when the n-type carrier stored region 106 is separated immediately under the center of the gate electrode 102, the n-type carrier stored region 106 is formed at a position deeper than those of the p-type base regions 105 to surround the p-type base regions 105, and a planar dimension of the n-type carrier stored region 106 (a width of the n-type carrier stored region 106 in a direction parallel to the first main surface and the second main surface) is made larger than a planar dimension of the p-type base regions 105 (a width of the p-type base regions 105 in the direction parallel to the first main surface and the second main surface). Thus, the breakdown voltage during non-conduction can be maintained without impairing the function of storing carriers during conduction.

Forming the n-type carrier stored region 106 and the p-type base regions 105 through ion implantation and a diffusion treatment and increasing the impurity concentration of the n-type carrier stored region 106 more than those of the p-type pillar regions 108 separate the p-type base regions 105 from the p-type pillar regions 108 by the n-type carrier stored region 106. As illustrated in FIG. 1, the p-type pillar regions 108 separated by the n-type carrier stored region 106 from the p-type base regions 105 become floating (an electrical floating state). This allows the n-type carrier stored region 106 sandwiched between the p-type pillar regions 108 and the p-type base regions 105 to function as a charge storage layer. However, the p-type pillar regions 108 and the p-type base regions 105 need not always be separated, for example, outside an active region that is an essential portion of a device. For example, connecting the p-type pillar regions 108 to the p-type base regions 105 in a region except the essential portion of the device can eject unnecessary carriers generated during operations of the device through contacts of an emitter electrode 100, and improve the long-term reliability and the ruggedness of the device.

### Method of Manufacturing Semiconductor Device According to Embodiment 1

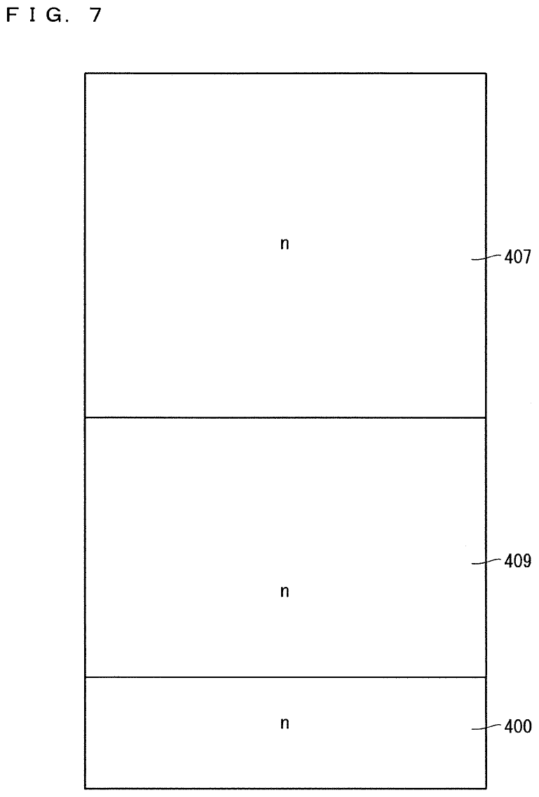

Next, wafer processes in the method of manufacturing the semiconductor device according to Embodiment 1 will be described. First, processes necessary for mainly forming the side of the first main surface will be described with reference to FIGS. 7 to 15. Here, only processes necessary for mainly manufacturing the essential portion of the device in FIG. 1 will be described. Thicknesses of an n-type bottom epitaxial layer 409 (the n-type bottom layer 109) and an n-type top epitaxial layer 407 (the drift layer 10) to be described later will be exemplified as thicknesses of super-junction IGBT elements belonging to approximately a 1200 V breakdown-voltage class. For example, a process not directly relevant to the present disclosure such as a cleaning treatment process prior to a gate oxide film, a sintering treatment process on, for example, an interlayer film and a metal wire, or a passivation film forming process, processes necessary for manufacturing a device termination structure, and an assembly process of dicing a device and assembling the diced devices into modules can be appropriately added.

First, as illustrated in FIG. 7, the n-type bottom epitaxial layer 409 doped with phosphorus on the order of, for example, approximately 10¹³ cm⁻³ is formed with a thickness of approximately 30 to 50 μm on, for example, an n-type silicon single-crystal substrate 400 doped with antimony. Then, the n-type top epitaxial layer 407 doped with phosphorus on the order of, for example, approximately 10¹⁵ cm⁻³ is formed with a thickness of approximately 50 to 70 μm on the n-type bottom epitaxial layer 409. As such, a semiconductor wafer in which the n-type bottom epitaxial layer 409 and the n-type top epitaxial layer 407 are formed on the n-type silicon single-crystal substrate 400 is prepared. Although an n-type substrate is exemplified as a silicon single-crystal substrate, the silicon single-crystal substrate may be a p-type substrate instead of the n-type substrate because the n-type silicon single-crystal substrate 400 is finally ground and removed, as will be described later. Although the impurity concentration of the semiconductor wafer is not restricted, the impurity concentration of the n-type bottom epitaxial layer 409 is preferably lower than that of the n-type top epitaxial layer 407 to obtain a desired breakdown voltage. The surface of the n-type top epitaxial layer 407 of the semiconductor wafer is the first main surface, and a surface opposite to the first main surface is the second main surface.

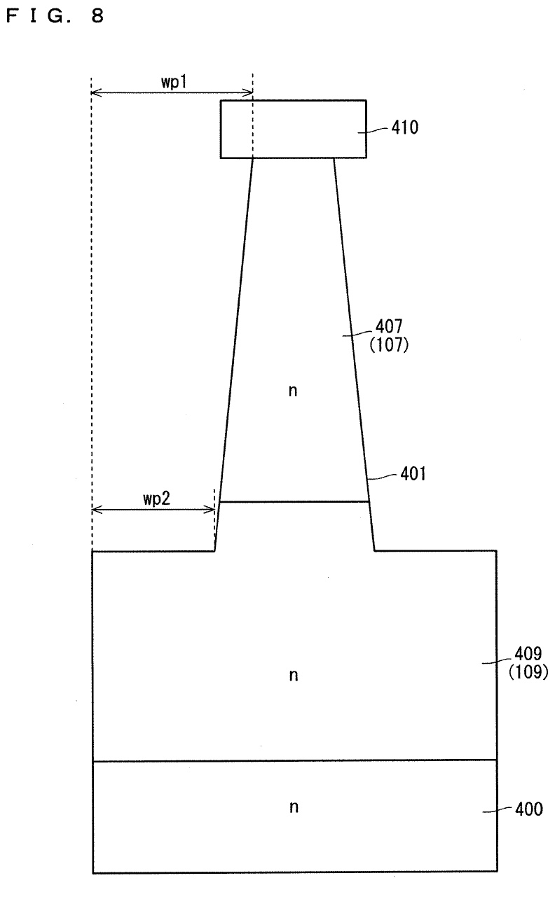

Next, a hardmask film 410 for forming trench grooves made of, for example, plasma-tetraethylorthosilicate (P-TEOS) is patterned on the first main surface as illustrated in FIG. 8. Then, dry etching the n-type top epitaxial layer 407 to reach the n-type bottom epitaxial layer 409, using the hardmask film for forming p-type-pillar-region trench grooves 401 as a mask forms the p-type-pillar-region trench grooves 401 (second-pillar-region trench grooves). Mesa portions sandwiched between the p-type-pillar-region trench grooves 401 become the n-type pillar regions 107. Furthermore, the n-type bottom epitaxial layer 409 corresponds to the n-type bottom layer 109. Although the bottom of the p-type-pillar-region trench grooves 401 preferably reaches the n-type bottom epitaxial layer 409, as long as impurities at the bottom of the p-type pillar regions 108 reach an interior of the n-type bottom layer 109 by a thermal diffusion process to be described later, the bottom of the p-type-pillar-region trench grooves 401 need not always reach the n-type bottom epitaxial layer 409 at this moment. Furthermore, boron may be ion-implanted into the bottom of the p-type-pillar-region trench grooves 401. Then, the unnecessary hardmask film 410 is removed.

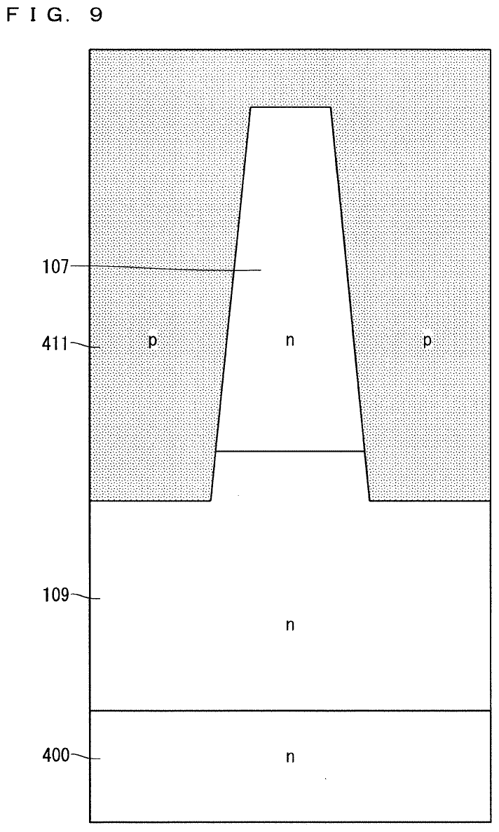

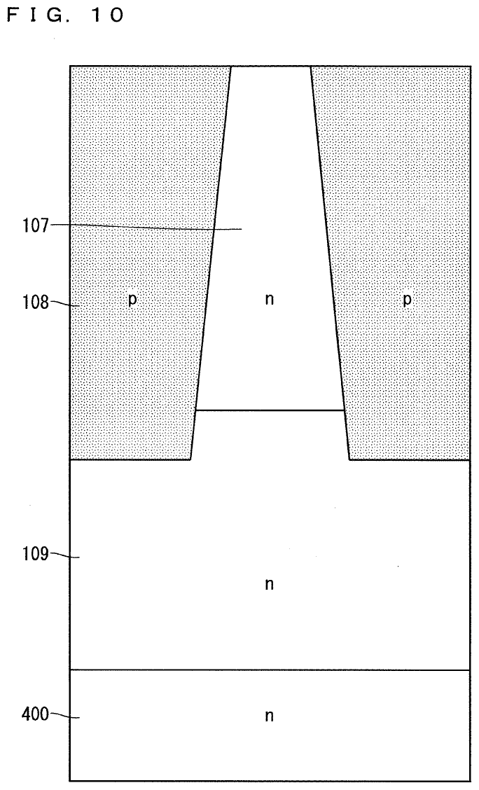

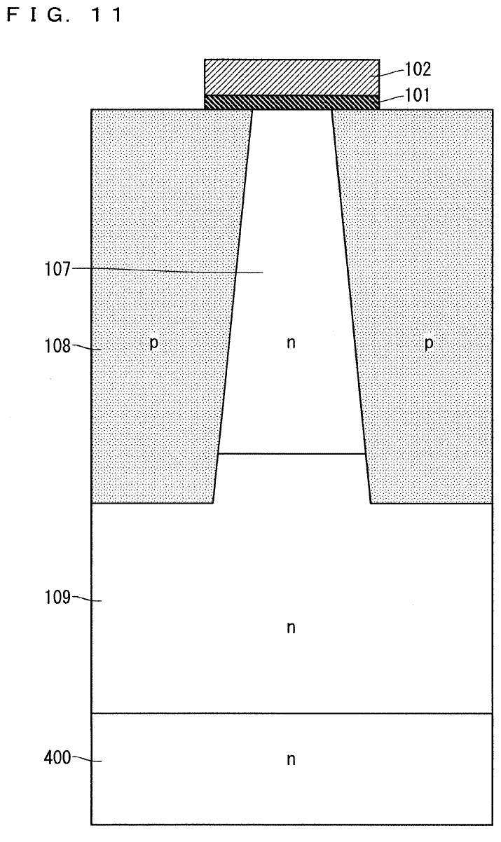

Next, as illustrated in FIG. 9, the p-type-pillar-region trench grooves 401 are subjected to an embedded epitaxial growth using a material doped with, for example, boron to embed an epitaxial layer into the p-type-pillar-region trench grooves 401. Here, an epitaxially-grown overgrowth region 411 is formed also on the n-type pillar regions 107 to completely embed the p-type-pillar-region trench grooves 401.

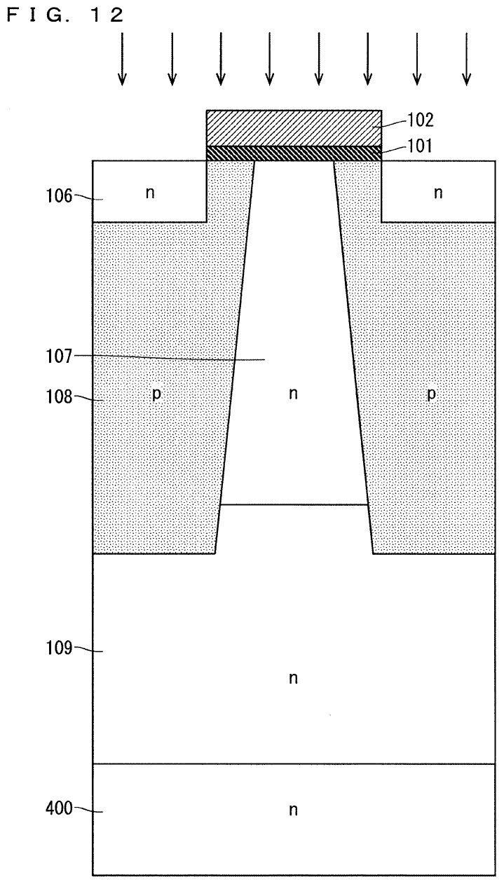

Next, as illustrated in FIG. 10, the overgrowth region 411 except the p-type-pillar-region trench grooves 401 is removed by, for example, a planarization process using chemical mechanical polishing (CMP), and the first main surface of the semiconductor wafer is planarized. Although a method of forming a super-junction structure using a trench-filling epitaxial embedding method is exemplified herein as illustrated in FIG. 10, the super-junction structure may be formed by a multi-epitaxial manufacturing method.

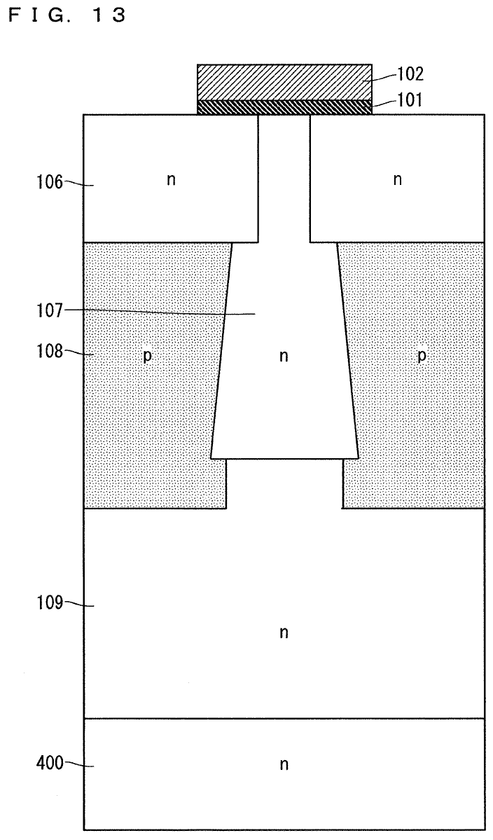

Next, as illustrated in FIG. 11, a gate oxide film is formed almost on the entirety of the first main surface of the semiconductor wafer through thermal oxidation, and a polysilicon film (corresponding to the gate electrode 102) is formed on the gate oxide film using, for example, low pressure chemical vapor deposition CVD. Then, dry etching the polysilicon film and the gate oxide film using a resist film as a mask through lithography to pattern the gate electrodes 102 and the gate insulating film 101. Although, for example, a Si oxide film of approximately 100 nm is exemplified as the gate insulating film 101 and the polysilicon film is exemplified as a material of the gate electrodes 102 herein, amorphous silicon or a metal such as molybdenum may be used as a material of the gate electrodes 102. Then, the unnecessary resist film is removed.

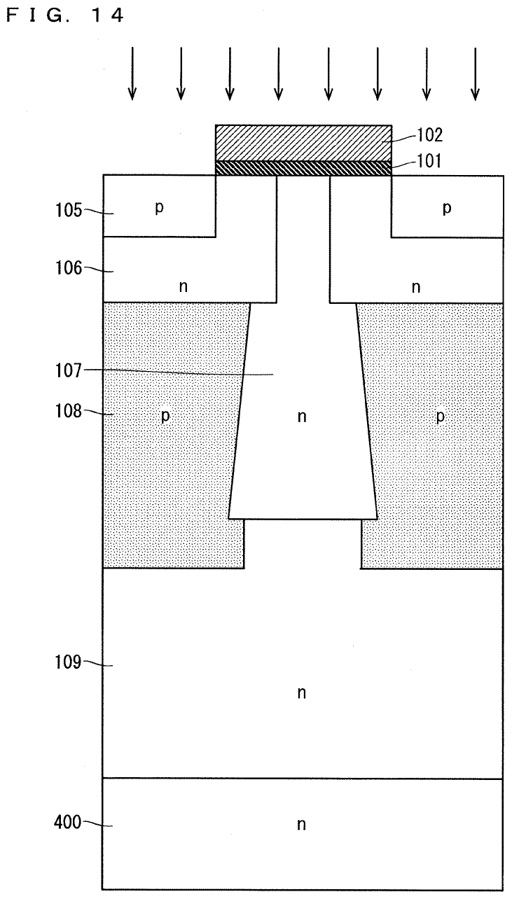

Next, as illustrated in FIG. 12, ion-implanting phosphorus of a dose of approximately 10¹⁴ cm⁻² forms the n-type carrier stored region 106.

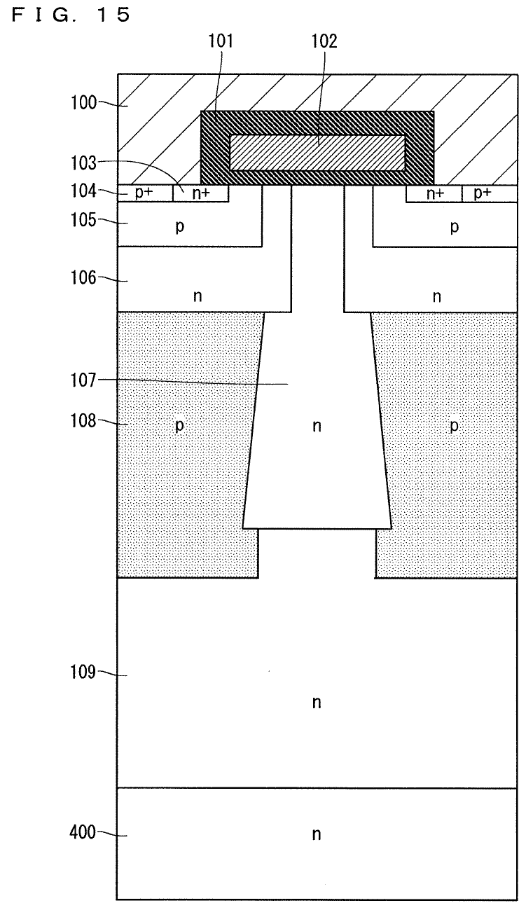

Next, as illustrated in FIG. 13, a thermal diffusion process at, for example, 1100 °C for approximately 140 minutes diffuses the n-type carrier stored region 106 to immediately under the gate electrodes 102. At the same time, diffusing boron at the bottom of the p-type pillar regions 108 into the n-type bottom layer 109 increases the width of the bottom of each of the p-type pillar regions 108.

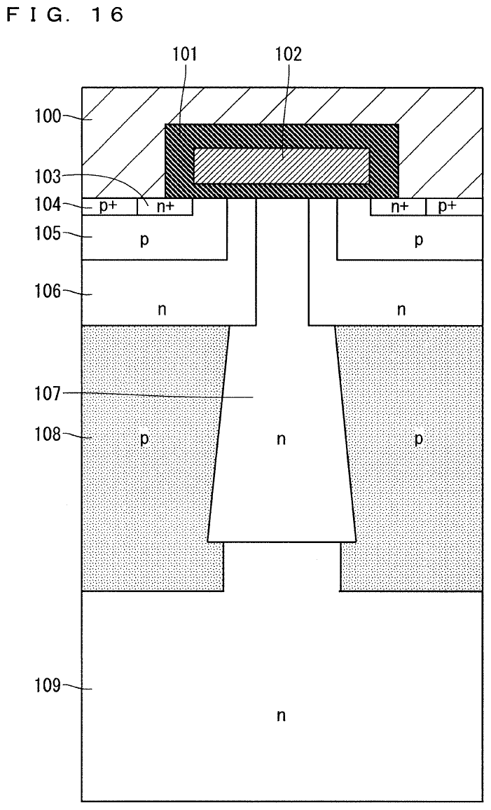

Next, as illustrated in FIG. 14, ion-implanting boron of a dose of, for example, approximately 3×10¹⁴ cm⁻² forms the p-type base regions 105. Then, performing a thermal diffusion process at, for example, 1100 °C for approximately 30 minutes diffuses the p-type base regions 105. Obviously, the n-type carrier stored region 106 and the bottom of the p-type pillar regions 108 on the n-type bottom layer 109 are further diffused here.

Next, ion-implanting, for example, antimony or arsenic of a dose of approximately 4×10¹⁵ cm⁻² using a resist film for an n-type emitter region as a mask through lithography forms the n-type emitter regions 103. Then, the unnecessary resist film for the n-type emitter region is removed. Then, ion-implanting, for example, boron of a dose of approximately 4×10¹⁵ cm⁻² using a resist film for a p-type body contact region as a mask through lithography forms the p-type body contact regions 104. Then, the n-type emitter regions 103 and the p-type body contact regions 104 are annealed at, for example, approximately 1000 °C through lamp heating or using a diffusion furnace to activate the n-type emitter regions 103 and the p-type body contact regions 104.

Next, a phosphosilicate glass (PSG) film is deposited almost on the entirety of the first main surface of the semiconductor wafer in CVD. Here, a borophosphosilicate glass (BPSG) film or a spin-on-glass (SOG) film may be overlaid thereon and planarized.

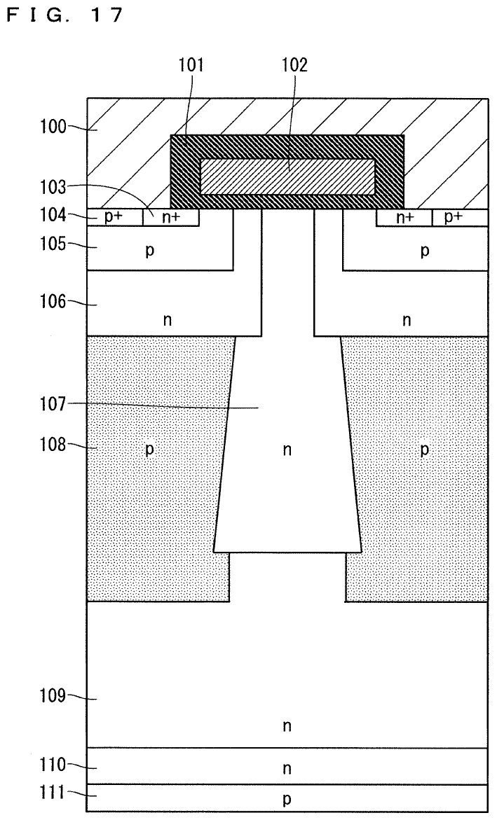

Next, as illustrated in FIG. 15, a resist film for opening emitter contact holes is formed to open emitter contact holes by dry etching using a resist film for opening emitter contact holes as a mask. Then, the unnecessary resist film is removed. Then, depositing an aluminum-based metal layer by sputtering through a barrier metal film made of, for example, TiW forms the emitter electrode 100.

Next, processes necessary for forming the side of the second main surface in the wafer processes in the method of manufacturing the semiconductor device according to Embodiment 1 will be described with reference to FIGS. 16 and 17.

As illustrated in FIG. 16, the n-type silicon single-crystal substrate 400 at the second main surface of the semiconductor wafer is completely removed, and the n-type silicon single-crystal substrate 400 is ground to expose the n-type bottom layer 109 in a surface layer of the second main surface. When the grinding damage remains on the ground second main surface, a grinding damage layer may be removed by a chemical etching treatment. Furthermore, when the second main surface is ground, it is preferred to protect an element structure formed on the side of the first main surface by, for example, applying a protection resist or sticking a protection tape to the first main surface.

Next, as illustrated in FIG. 17, ion-implanting phosphorus of a dose of, for example, approximately 5×10¹² cm⁻² on the second main surface of the semiconductor wafer to form the n-type buffer layer 110. Then, ion-implanting boron of a dose of, for example, approximately 1×10¹³ cm⁻² forms the p-type collector layer 111 at a position shallower than the n-type buffer layer 110 (a position on the side of the second main surface). Then, the n-type buffer layer 110 and the p-type collector layer 111 are activated by, for example, a laser annealer.

### Modification of Embodiment 1

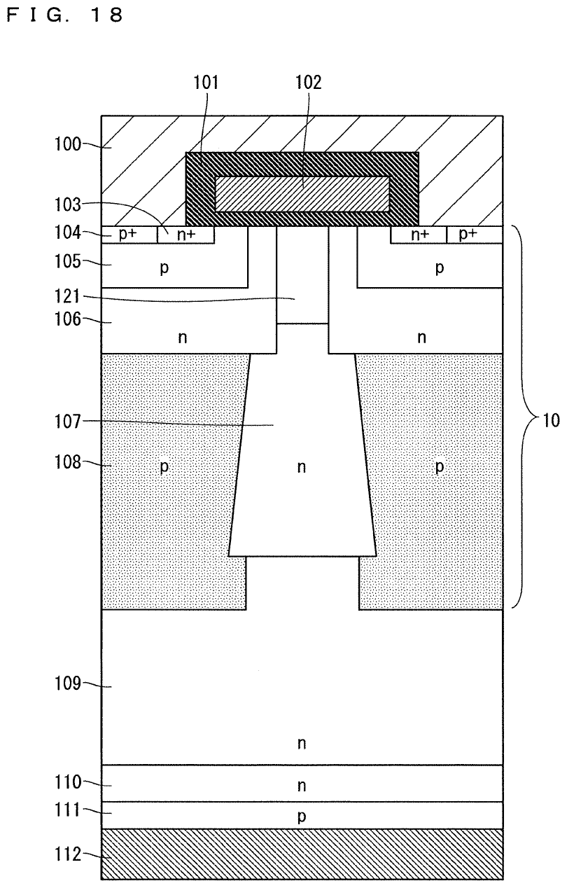

FIG. 18 is a cross-sectional view schematically illustrating a structure of a semiconductor device according to a modification of Embodiment 1. In FIG. 18, the same reference numerals are attached to portions identical to those of FIG. 1, and the description will be omitted. The semiconductor device according to this modification differs from the semiconductor device according to Embodiment 1 by newly disposing an n-type JFET region 121 higher in impurity concentration than the n-type pillar regions 107, between the n-type carrier stored regions 106 extending in the vertical direction with respect to the paper of FIG. 18 and arranged in stripes.

In the semiconductor device according to this modification, the n-type JFET region 121 can reduce a width of the depletion layer extending from the p-type base regions 105, during conduction achieved by injecting electrons from the inversion layer formed in a surface of the adjacent p-type base regions 105 to an upper portion of the n-type pillar regions 107.

A structure of separating the n-type carrier stored regions 106 arranged in stripes using the n-type pillar regions 107 as in a conventional semiconductor device has a problem in that reduction of cell pitches causes the depletion layer extending from the p-type base regions 105 to narrow the current paths between the adjacent n-type carrier stored regions 106 and increase the ON resistance of the semiconductor device. Forming the n-type JFET region 121 according to this modification can solve such a problem and reduce the ON resistance.

### Embodiment 2

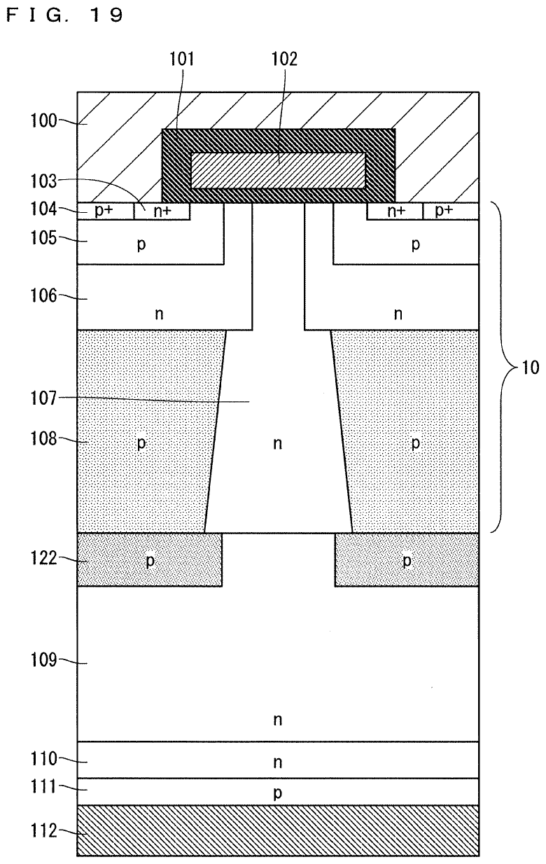

FIG. 19 is a cross-sectional view schematically illustrating a structure of a semiconductor device according to Embodiment 2. In FIG. 19, the same reference numerals are attached to portions identical to those of FIG. 1, and the description will be omitted. The semiconductor device according to Embodiment 2 differs from the semiconductor device according to Embodiment 1 in that p-type pillar bottom regions 122 deeper than the lower end of the n-type pillar regions 107 (at positions on the side of the second main surface) contain impurities with a concentration higher than that of the p-type pillar regions 108 closer to the side of the first main surface than the p-type pillar bottom regions 122.

As illustrated in FIG. 19, the p-type pillar bottom regions 122 are located at positions deeper than the lower end of the n-type pillar regions 107, and are located under the p-type pillar regions 108. Furthermore, the p-type pillar bottom regions 122 are higher in impurity concentration than the p-type pillar regions 108. Forming the p-type pillar bottom regions 122 can enhance the electric field of the n-type bottom layer 109 more. Consequently, for example, when a thickness of the drift layer 10 necessary for obtaining a desired breakdown voltage cannot be sufficiently ensured, making the p-type pillar bottom regions 122 located at the positions deeper than the lower end of the n-type pillar regions 107, higher in impurity concentration than the p-type pillar regions 108 located higher than the p-type pillar bottom regions 122 can increase the burden on the voltage shared by the n-type bottom layer 109. Thus, the breakdown voltage can be improved.

### Modifications 1 and 2 of Embodiment 2

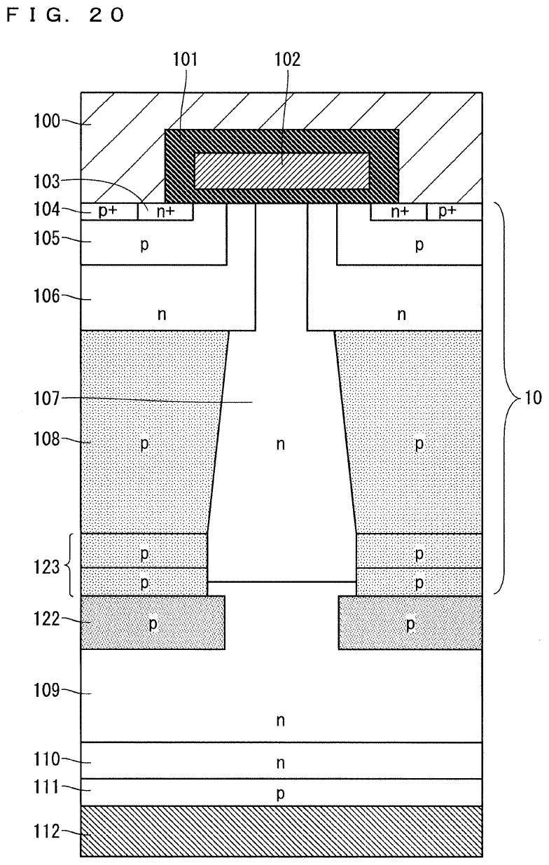

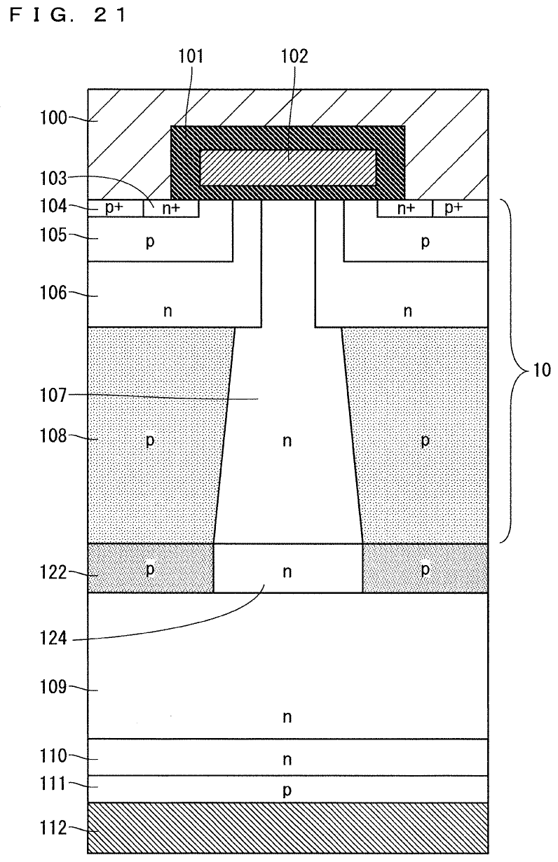

FIG. 20 is a cross-sectional view schematically illustrating a structure of a semiconductor device according to Modification 1 of Embodiment 2. FIG. 21 is a cross-sectional view schematically illustrating a structure of a semiconductor device according to Modification 2 of Embodiment 2. In FIGS. 20 and 21, the same reference numerals are attached to portions identical to those of FIG. 19, and the description will be omitted.

The semiconductor device according to Modification 1 in FIG. 20 differs from the semiconductor device according to Embodiment 2 in that the p-type pillar bottom regions 122 and 123 include a plurality of regions with different widths and different impurity concentrations in the depth direction. The p-type pillar bottom regions 122 in the semiconductor device according to Modification 1 in FIG. 20 are formed as only extensions of the p-type pillar regions 108. This point differs from the semiconductor device according to Modification 1.

Furthermore, the semiconductor device according to Modification 2 in FIG. 21 differs from the semiconductor device according to Embodiment 2 by including an n-type JFET region 124 higher in impurity concentration than the n-type pillar regions 107, between the adjacent p-type pillar bottom regions 122. The n-type JFET region 124 is in contact with the lower end of the n-type pillar regions 107. The semiconductor device according to Modification 2 is identical to that according to Embodiment 2 or Modification 1 in that the p-type pillar bottom regions 122 differ in impurity concentration from the p-type pillar regions 108.

In the semiconductor device according to Embodiment 2 in FIG. 19, the single p-type pillar bottom region 122 higher in impurity concentration than the p-type pillar regions 108 located shallower than the lower end of the n-type pillar regions 107 is disposed. The semiconductor device according to Modification 1 in FIG. 20 includes the plurality of p-type pillar bottom regions 123 disposed in the depth direction, which can control an electric field distribution more minutely.

Furthermore, increasing the impurity concentration of the p-type pillar bottom regions 122 to improve the breakdown voltage extends the depletion layers between the adjacent p-type pillar bottom regions 122 and increases the ON voltage. To address this, the n-type JFET region 124 higher in impurity concentration than the n-type pillar regions 107 is disposed between the p-type pillar bottom regions 122 in the semiconductor device according to Modification 2 in FIG. 21. This can make improvement of the breakdown voltage compatible with reduction in the ON resistance.

### Embodiment 3

### Structure of Semiconductor Device According to Embodiment 3

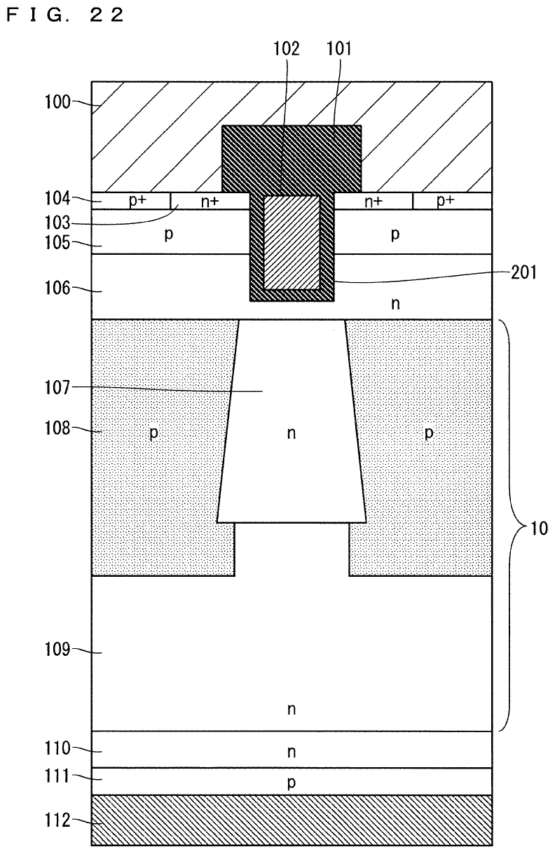

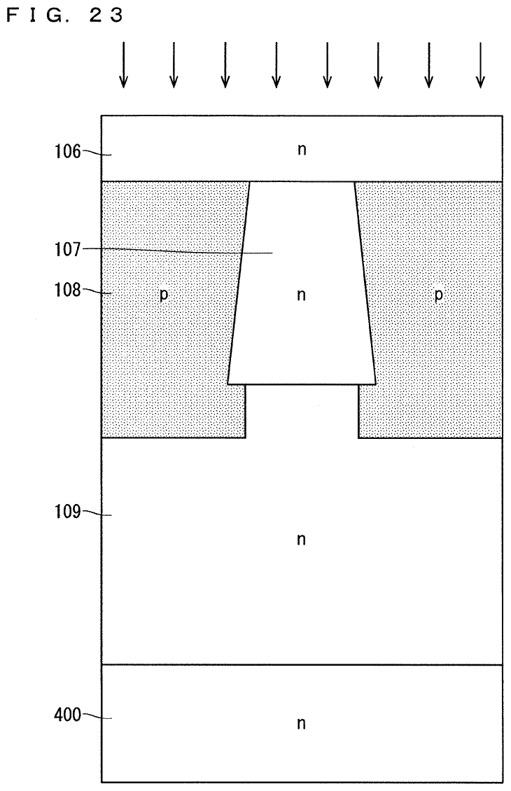

FIG. 22 is a cross-sectional view illustrating a structure of a semiconductor device according to Embodiment 3. The semiconductor device according to Embodiment 3 is a trench-gate super-junction IGBT element manufactured using a silicon-based semiconductor substrate. Although a semiconductor device of which emitter-to-collector breakdown voltage is approximately 1200 bolt is specifically described hereinafter as an example, the following description is applicable to super-junction IGBT elements with other breakdown voltage values or semiconductor devices with other super-junction structures.

The semiconductor device according to Embodiment 3 differs from the semiconductor device according to Embodiment 1 in that the semiconductor device according to Embodiment 1 is a planar-gate MOS semiconductor device, whereas the semiconductor device according to Embodiment 3 is a trench-gate MOS semiconductor device.

As illustrated in FIG. 22, the n-type carrier stored region 106 separates the upper end of the p-type pillar regions 108 from the p-type base regions 105 selectively formed above the p-type pillar regions 108 on the side of the first main surface. Trench grooves 201 are selectively arranged above the n-type pillar regions 107 such that the trench grooves 201 penetrate the p-type base regions 105 from the n-type emitter regions 103 of a low resistance which are formed in a surface layer of the p-type base regions 105, and reach a part of the n-type carrier stored region 106. In each of the trench grooves 201, the gate electrode 102 is disposed through the gate insulating film 101.

The depth position of the bottom (lower end) of the trench groove 201 is shallower than the depth position of the upper end of the p-type pillar regions 108. This can prevent a decrease in the breakdown voltage which is caused by an increase in the electric field between the upper portion of the p-type pillar regions 108 and the trench grooves 201.

### Method of Manufacturing Semiconductor Device According to Embodiment 3

Next, wafer processes in the method of manufacturing the semiconductor device according to Embodiment 3 will be described with reference to FIGS. 23 to 26. Although only processes necessary for mainly manufacturing the essential portion of the device in FIG. 22 will be described herein, the description on processes up to manufacturing the super-junction IGBT elements on the side of the first main surface will be omitted because the processes are common to those in the method of manufacturing the planar-gate super-junction IGBT element as illustrated in FIGS. 7 to 10. Since the processes on the side of the second main surface are basically identical to those in FIG. 16 or the subsequent drawings, only the differences will be described herein.

After a super-junction structure is formed on the n-type silicon single-crystal substrate 400 on the side of the first main surface, ion-implanting phosphorus of a dose of, for example, approximately 10¹⁴ cm⁻² to form the n-type carrier stored region 106 as illustrated in FIG. 23.

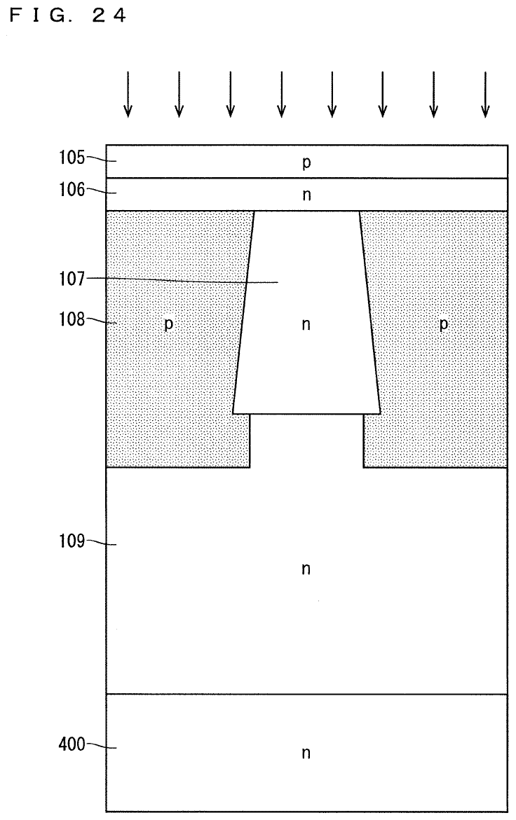

Next, as illustrated in FIG. 24, ion-implanting boron of a dose of, for example, approximately 3×10¹⁴ cm⁻² forms the p-type base region 105.

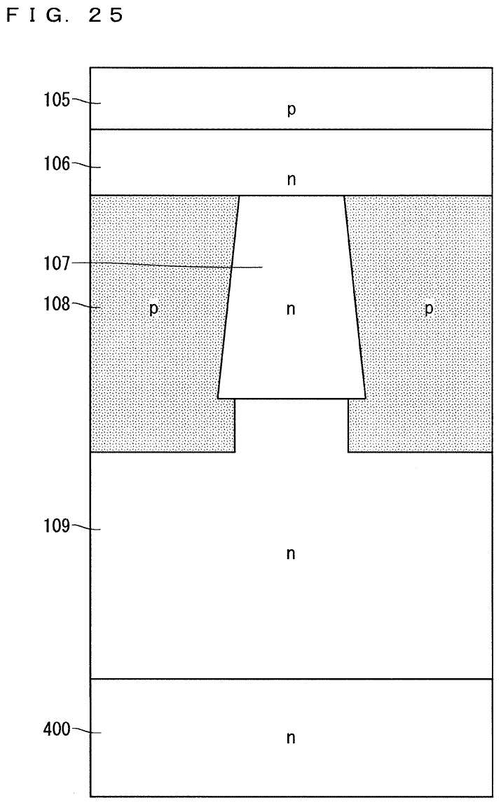

Next, as illustrated in FIG. 25, a thermal diffusion process at, for example, 1100 °C for approximately 140 minute diffuses the n-type carrier stored region 106 and the p-type base region 105. At the same time, diffusing boron at the bottom of the p-type pillar regions 108 into the n-type bottom layer 109 increases the width of the bottom of each of the p-type pillar regions 108.

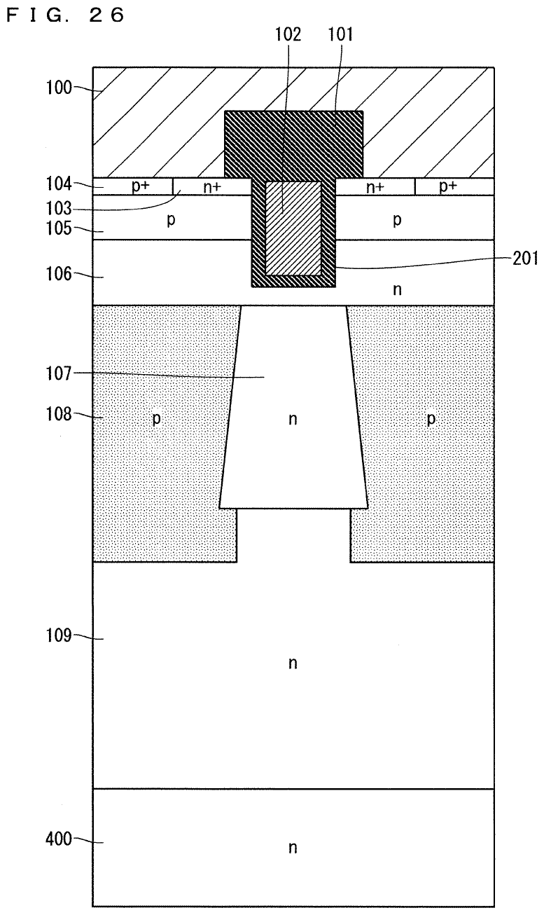

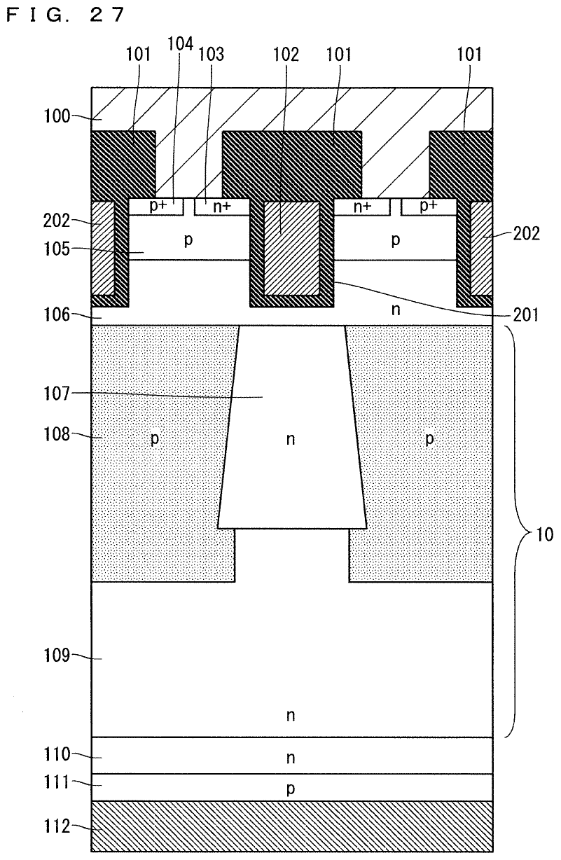

Next, a trench-gate MOSFET in which the gate electrode 102 is embedded in each of the trench grooves 201 (gate trench grooves) through the gate insulating film 101 is formed as illustrated in FIG. 26.

Although the trench-gate structure is formed after the p-type base region 105 is formed in FIGS. 25 and 26, conversely, the p-type base region 105 may be formed after the trench-gate structure is formed first.

### Modification of Embodiment 3

FIG. 27 is a cross-sectional view schematically illustrating a structure of a semiconductor device according to a modification of Embodiment 3. The same reference numerals are attached to portions identical to those of FIG. 22, and the description will be omitted. The semiconductor device according to this modification differs from the semiconductor device according to Embodiment 3 in that only the gate electrode 102 is formed in each of the trench grooves 201 in the semiconductor device according to Embodiment 3, whereas the n-type emitter region 103 is not formed, on the side of the first main surface, in the p-type base regions 105 which are in contact with sidewalls of some of the trench grooves 201 in this modification. As such, dummy gate electrodes 202 are formed through the gate insulating film 101 in the trench grooves 201 in contact with the p-type base regions 105 on the side of the first main surface of which the n-type emitter region 103 is not formed. The dummy gate electrodes 202 embedded in the trench grooves 201 of trench dummy gates may be connected to the gate electrodes 102 or the emitter electrode 100.

Since the n-type emitter region 103 is not formed, on the side of the first main surface, in the p-type base regions 105 which are in contact with the sidewalls of the trench grooves 201 of the trench dummy gates and electrons are not injected through the sidewalls of the trench grooves 201 of the trench dummy gates, the trench dummy gates are referred to as such to distinguish from original gates (trench gates). In this modification, disposing these trench dummy gates, for example, above the p-type pillar regions 108 can enhance the hole storing effect and reduce the ON voltage.

As illustrated in FIG. 22, narrowing spacing between the trench grooves 201 to reduce the ON resistance in a semiconductor device consisting of trench gates increases a saturation current because of an increase in the channel density. When a load such as a motor is short-circuited, a larger saturation current poses a danger of passing a larger current and destroying elements. Thus, the structure using the trench dummy gates is an effective means when narrowing only trench pitches is desired without increasing the channel density.

It is preferred that the trench grooves 201 of the trench dummy gates are disposed above the p-type pillar regions 108 and the trench grooves 201 of the trench gates are disposed above the n-type pillar regions 107. This enables electrons to be efficiently injected from the n-type emitter regions 103 into the n-type carrier stored region 106 and the n-type pillar regions 107 under the n-type carrier stored region 106 through the inversion layer formed in the p-type base regions 105 in the vicinity of the sidewalls of the trench grooves 201 of the trench gates.

High electric charges occurring in switching operations generate dynamic avalanche, and hot carriers generated by the avalanche may be trapped by a MOS interface of the trench dummy gates above the p-type pillar regions 108. When the p-type pillar regions 108 are floating, storing the charges trapped at the bottom of the trench grooves 201 above the p-type pillar regions 108 for long-term operations gradually throws off the charge balance in the vicinity of the upper end of the p-type pillar regions 108 and impairs the long-term reliability. Thus, a structure of connecting the p-type pillar regions 108 to the p-type base regions 105, for example, in a termination structure region outside of an active region or in a gate lead wiring region and separating the p-type pillar regions 108 from the p-type base regions 105 in the active region can make reduction in the ON resistance compatible with ensuring the long-term reliability.

### Embodiment 4

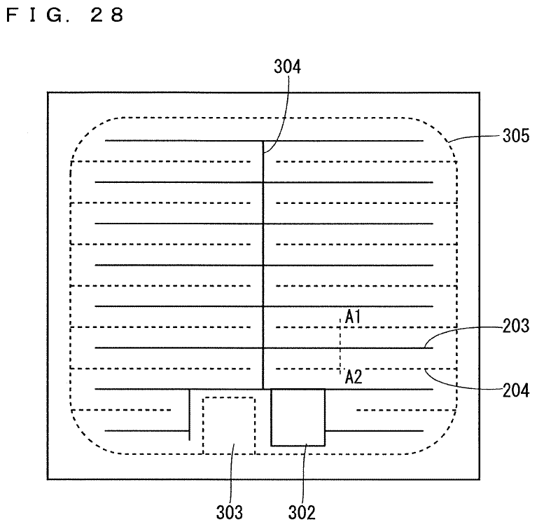

FIG. 28 is a plan view schematically illustrating a top layout of a semiconductor device according to Embodiment 4. As illustrated in FIG. 28, first gate electrodes 203 and second gate electrodes 204 are alternately disposed in the active region. The plurality of first gate electrodes 203 disposed in the active region are bound in the vicinity of the center of the top layout (connected to a first gate wire 304), and are electrically connected to a first gate electrode pad 302. Furthermore, the plurality of second gate electrodes 204 disposed in the active region are bound around the active region (connected to a second gate wire 305), and are electrically connected to a second gate electrode pad 303. As will be described later, disposing the first gate electrodes 203 above the n-type pillar regions 107 and disposing the second gate electrodes 204 above the p-type pillar regions 108 can drive the gates individually and perform finely-tuned control appropriate for, for example, reducing the switching loss.

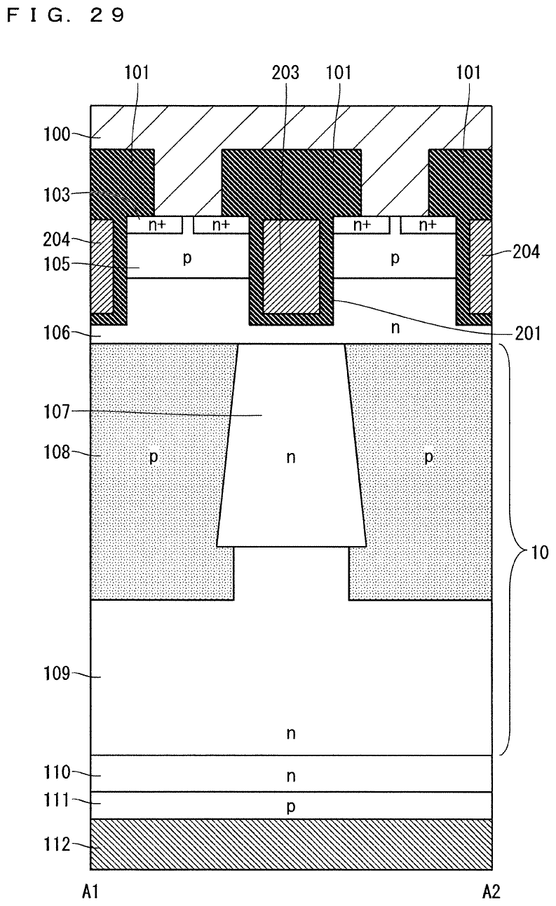

FIG. 29 is a cross-sectional view schematically illustrating a structure of an A1-A2 portion of the semiconductor device according to Embodiment 4 in FIG. 28. The semiconductor device according to Embodiment 4 is a trench-gate super-junction IGBT element manufactured using a silicon-based semiconductor substrate. The semiconductor device according to Embodiment 4 differs from the semiconductor devices according to Embodiments 1 to 3 by including gates of two types to which different voltages can be applied.

As illustrated in FIG. 29, the n-type carrier stored region 106 separates the upper end of the p-type pillar regions 108 from the p-type base regions 105 selectively formed above the p-type pillar regions 108 on the side of the first main surface. The trench grooves 201 are selectively arranged above the n-type pillar regions 107 such that the trench grooves 201 penetrate the p-type base regions 105 from the n-type emitter regions 103 of a low resistance which are formed in a surface layer of the p-type base regions 105 and reach a part of the n-type carrier stored region 106. In the trench grooves 201, the first gate electrodes 203 are disposed to face the n-type pillar regions 107 through the gate insulating film 101.

Furthermore, the trench grooves 201 are selectively arranged above the p-type pillar regions 108 such that the trench grooves 201 penetrate the p-type base regions 105 from the n-type emitter regions 103 of the low resistance which are formed in a surface layer of the p-type base regions 105 and reach a part of the n-type carrier stored region 106. In the trench grooves 201, the second gate electrodes 204 are disposed to face the p-type pillar regions 108 through the gate insulating film 101.

As illustrated in FIG. 28, the first gate electrodes 203 are disposed to divide the active region of the semiconductor device, and the second gate electrodes 204 are disposed from the outermost circumference to the inner circumference in the active region. The first gate electrodes 203 span the first gate wire 304, and the second gate electrodes 204 span the second gate wire 305. The first gate wire 304 and the second gate wire 305 are routed and disposed on the upper surface of the semiconductor device. The first gate wire 304 is electrically connected to the first gate electrode pad 302, and the second gate wire 305 is electrically connected to the second gate electrode pad 303. Although the first gate wire 304 and the second gate wire 305 may be made of polysilicon or amorphous silicon, they are preferably made of a metal wiring material such as aluminum to further reduce the delay of a gate signal.

Although FIG. 28 illustrates a layout in which the first gate electrodes 203 span the first gate wire 304 in the active region to divide the active region of the semiconductor device and the second gate electrodes 204 span the second gate wire 305 around the semiconductor device, the first gate electrodes 203 may span the first gate wire 304 around the semiconductor device and the second gate electrodes 204 may span the second gate wire 305 in the active region. Obviously, the same advantages can be expected from not the layout of the gate wires for dividing the active region but a layout in which the first gate electrodes 203 and the second gate electrodes 204 are alternately connected from the right and the left or up and down in the active region toward the active region.

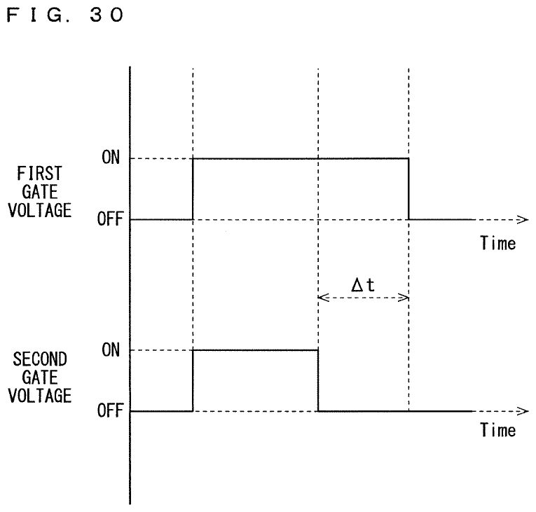

FIG. 30 is a graph exemplifying a timing chart of the first gate voltage and the second gate voltage for driving the semiconductor device according to Embodiment 4. The first gate voltage is applied to the first gate electrode pad 302, whereas the second gate voltage is applied to the second gate electrode pad 303.

### Operations of Semiconductor Device According to Embodiment 4

The operations of the semiconductor device according to Embodiment 4 will be described.

The semiconductor device according to Embodiment 4 includes the drift layer 10 including the n-type pillar regions 107 and the p-type pillar regions 108 which makes up a super-junction structure.

while the emitter electrode 100 is grounded and the power supply voltage is applied to the collector electrode 112, when the first gate voltage is lower than or equal to a gate threshold voltage of the MOSFET formed in the first main surface, a reverse bias is applied between the p-type base regions 105 and the drift layer 10, and the collector electrode 112 and the emitter electrode 100 are in an OFF state where the current is interrupted.

Next, simultaneously applying voltages exceeding the gate threshold voltage of the MOSFET formed in the first main surface to the first gate electrodes 203 and the second gate electrodes 204 as the first gate voltage and the second gate voltage, respectively, forms an n-type inversion layer in portions of the p-type base regions 105 which are in contact with the first gate electrodes 203 and the second gate electrodes 204 through the gate insulating film 101. Then, conducting the electric current from the collector electrode 112 to the emitter electrode 100 through this inversion layer allows the semiconductor device to enter the ON state that is turned ON from an OFF state.

To set the current flowing through the semiconductor device in this ON state again to the OFF state, a zero bias or a negative bias is applied to the second gate electrodes 204 as the second gate voltage, and a zero bias or a negative bias is applied to the first gate electrodes 203 as the first gate voltage after a lapse of the time Δt since the initial application as illustrated in FIG. 30. Once the n-type inversion layer generated at the MOS interface of the p-type base regions 105 in contact with the first gate electrodes 203 and the second gate electrodes 204 through the gate insulating film 101 disappears, supplying electrons from the n-type emitter regions 103 to the drift layer 10 is stopped. Stored carriers in the drift layer 10 and the n-type bottom layer 109 are attenuated, and depletion layers between the p-type pillar regions 108 and the n-type pillar regions 107 in the drift layer 10 are punched through to increase the voltage between the collector electrode 112 and the emitter electrode 100 and set the semiconductor device to an OFF state.

Here, Δt is suitable between 0.1 microseconds and 10 microseconds.

### Effects and Advantages of Semiconductor Device According to Embodiment 4

The effects and advantages of the semiconductor device according to Embodiment 4 will be described.

In a process of turning OFF the semiconductor device, first, an OFF signal is given to the second gate electrodes 204 formed above the p-type pillar regions 108 as the second gate voltage. Then, the n-type inversion layer generated at the MOS interface of the p-type base regions 105 in contact with the second gate electrodes 204 disappears, and supplying electrons from the n-type emitter regions 103 adjacent to the second gate electrodes 204 through the gate insulating film 101 is stopped. Here, a p-type inversion layer is formed in a portion of the n-type carrier stored region 106 in contact with the second gate electrodes 204 through the gate insulating film 101. This forms a PNP bipolar transistor using the p-type pillar regions 108 as a p-type emitter, using the n-type carrier stored region 106 as an n-type base, and using the p-type inversion layer as a p-type collector. Forming such a PNP bipolar transistor ejects the holes from the upper portion of the p-type pillar regions 108 to the p-type base regions 105 through the n-type carrier stored region 106 and the p-type inversion layer. This ejects the carriers stored in the drift layer 10, so that a depletion layer extends between p-n junctions of the p-type pillar regions 108 and the n-type pillar regions 107 in the drift layer 10 and up to a part of a region of the n-type bottom layer. At this moment, the super-junction region is not completely depleted.

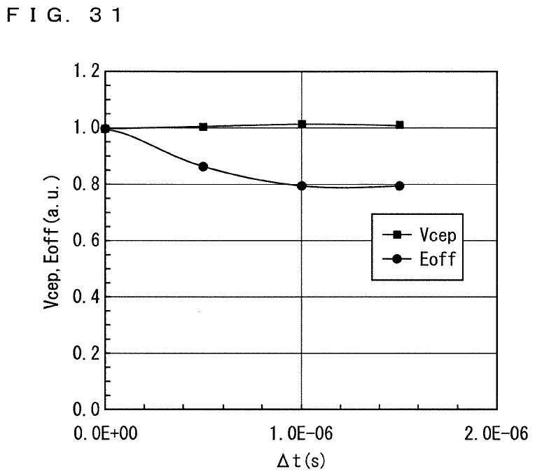

After the delay time Δt in which the OFF signal is given to the second gate electrodes 204 as the second gate voltage, a zero bias or a negative bias is applied to the first gate electrodes 203 as the first gate voltage. Since the n-type inversion layer generated at the MOS interface of the p-type base regions 105 in contact with the first gate electrodes 203 through the gate insulating film 101 also disappears, supplying electrons from the n-type emitter regions 103 is completely stopped. Since the OFF signal is first given to the second gate electrodes 204 as the second gate voltage, the time necessary for completely depleting the drift layer 10 becomes shorter as Δt increases. We confirmed this in simulation and that the turn off loss Eoff decreases and is saturated at a certain point as Δt increases, as illustrated in FIG. 31. While carriers are also stored in the n-type bottom layer 109, a depletion layer enters the n-type bottom layer 109 at the timing when one of the first gate electrodes 203 or the second gate electrodes 204 are turned OFF, and the collector-to-emitter voltage is peaked. Thus, the surge voltage Vcep hardly affects Δt. Thus, Δt>0 can reduce the turn off loss Eoff without increasing the surge voltage Vcep at turn off time.

### Modification of Embodiment 4

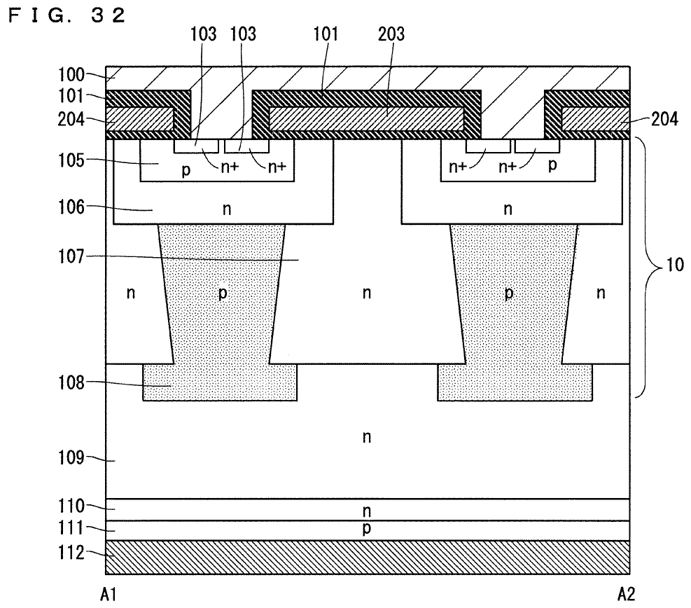

FIG. 32 is a cross-sectional view schematically illustrating a structure of a semiconductor device according to a modification of Embodiment 4. The same reference numerals are attached to portions identical to those of FIG. 29, etc., and the description will be omitted. The semiconductor device according to this modification differs from the semiconductor device according to Embodiment 4 in that the semiconductor device according to this modification has a planar gate structure.

When the OFF signal is given to the second gate electrodes 204 as the second gate voltage earlier by the time Δt than when the OFF signal is given to the first gate electrodes 203 as the first gate voltage in the semiconductor device according to this modification, the n-type inversion layer generated at the MOS interface of the p-type base regions 105 in contact with the second gate electrodes 204 disappears, and supplying electrons from the n-type emitter regions 103 adjacent to the second gate electrodes 204 through the gate insulating film 101 is stopped. Here, a p-type inversion layer is formed in a portion of the n-type carrier stored region 106 in contact with the second gate electrodes 204 through the gate insulating film 101. Since the p-type inversion layer is connected to both of the p-type base regions 105 and the p-type pillar regions 108, the stored carriers in the drift layer 10 are ejected to the emitter electrode 100 connected to the p-type base regions 105, through the p-type pillar regions 108 and the p-type inversion layer. Thus, when the OFF signal is given to the first gate electrodes 203 as the first gate voltage, the time for completely depleting the drift layer 10 is shortened. Thus, the turn off loss can be reduced without increasing the surge voltage.

Embodiments can be freely combined, and appropriately modified or omitted within the scope of the present disclosure.

While the present disclosure is described in detail, the foregoing description is in all aspects illustrative and does not restrict the present disclosure. Thus, numerous modifications that have yet been exemplified will be devised.

### EXPLANATION OF REFERENCE SIGNS

10 drift layer, 100 emitter electrode, 101 gate insulating film, 102 gate electrode, 103 n-type emitter region, 104 p-type body contact region, 105 p-type base region, 106 n-type carrier stored region, 107 n-type pillar region, 108 p-type pillar region, 109 n-type bottom layer, 110 n-type buffer layer, 111 p-type collector layer, 112 collector electrode, 121 n-type JFET region, 122 p-type pillar bottom region, 123 p-type pillar bottom region, 124 n-type JFET region, 201 trench groove, 202 dummy gate electrode, 203 first gate electrode, 204 second gate electrode, 302 first gate electrode pad, 303 second gate electrode pad, 304 first gate wire, 305 second gate wire, 400 n-type silicon single-crystal substrate, 401 p-type-pillar-region trench groove, 407 n-type top epitaxial layer, 409 n-type bottom epitaxial layer, 410 hardmask film, 411 overgrowth region.

1. A semiconductor device having a first main surface, and a second main surface facing the first main surface, the semiconductor device comprising:
a drift layer including a first pillar region of a first conductivity type and a second pillar region of a second conductivity type, the first pillar region and the second pillar region being alternately disposed in a direction parallel to the first main surface and the second main surface;
a base region of the second conductivity type, the base region being selectively disposed in the drift layer on a side of the first main surface;
a gate insulating film disposed in contact with the base region;
a gate electrode disposed to face the base region through the gate insulating film;
a carrier stored region of the first conductivity type, the carrier stored region being disposed between the base region and the second pillar region; and
an emitter region of the first conductivity type, the emitter region being selectively disposed in a surface layer of the base region on the side of the first main surface,
wherein a lower end of the second pillar region that is an end portion on a side of the second main surface is located closer to the side of the second main surface than a lower end of the first pillar region that is an end portion on the side of the second main surface, and
wp3>wp2 and wp1>wp2 hold, where wp1 denotes a width of an upper end of the second pillar region that is an end portion on the side of the first main surface, wp2 denotes a width of the second pillar region at a same position as a lower end of the first pillar region, and wp3 denotes a width of the lower end of the second pillar region.

2. The semiconductor device according to claim 1, further comprising:
a bottom layer of the first conductivity type, the bottom layer being disposed on the side of the second main surface with respect to the drift layer;
a buffer layer of the first conductivity type, the buffer layer being disposed on the side of the second main surface with respect to the bottom layer; and
a collector layer of the second conductivity type, the collector layer being disposed on the side of the second main surface with respect to the buffer layer.

3. The semiconductor device according to claim 1,
wherein the carrier stored region is separated at a position corresponding to a center of the gate electrode in the direction parallel to the first main surface and the second main surface.

4. The semiconductor device according to claim 3,
wherein the carrier stored region is greater in width than the base region in the direction parallel to the first main surface and the second main surface.

5. The semiconductor device according to claim 1,
wherein in the second pillar region, a concentration of impurities contained in a region from the same position as the lower end of the first pillar region to the lower end of the second pillar region is higher than a concentration of impurities contained in a region from the upper end of the second pillar region to the same position as the lower end of the first pillar region.

6. The semiconductor device according to claim 5, further comprising
a JFET region of the first conductivity type, the JFET region being disposed on the side of the second main surface with respect to the first pillar region and disposed in contact with the lower end of the first pillar region,
wherein the JFET region is higher in impurity concentration than the first pillar region.

7. The semiconductor device according to claim 1,
wherein the gate electrode penetrates the base region and reach the carrier stored region.

8. The semiconductor device according to claim 1,
wherein the second pillar region is connected to the base region.

9. The semiconductor device according to claim 1,
wherein the second pillar region is partly separated from the base region.

10. The semiconductor device according to claim 7,
wherein the gate electrode includes a first gate electrode and a second gate electrode,
the first gate electrode is disposed to face the first pillar region through the gate insulating film, and
the second gate electrode is disposed to face the second pillar region through the gate insulating film.

11. A method for controlling a semiconductor device, the method comprising
giving an OFF signal to the second gate electrode before giving an OFF signal to the first gate electrode, when an ON state in which an electric current is conducted to the semiconductor device according to claim 10 is switched to an OFF state in which the electric current is not conducted.

12. A method of manufacturing a semiconductor device, the method comprising the steps of:
(a) preparing a semiconductor wafer in which a bottom epitaxial layer of a first conductivity type is formed on a semiconductor substrate and a top epitaxial layer of the first conductivity type is formed on a surface layer of the bottom epitaxial layer;
(b) forming a second-pillar-region trench groove to penetrate the top epitaxial layer and reach the bottom epitaxial layer, and forming the top epitaxial layer excluding the second-pillar-region trench groove as a first pillar region;
(c) subjecting the second-pillar-region trench groove to an embedded epitaxial growth using a material doped with impurities of a second conductivity type to form a second pillar region;
(d) planarizing a first main surface to expose the first pillar region and the second pillar region in the first main surface, the first main surface being a surface of the semiconductor wafer on a side of the top epitaxial layer;
(e) forming a gate insulating film covering the first pillar region and extending from the first pillar region to a part of the second pillar region, and forming a gate electrode on the gate insulating film;
(f) implanting ions from a side of the first main surface to form a carrier stored region of the first conductivity type in a surface layer of the second pillar region;
(g) performing a thermal diffusion process to diffuse the carrier stored region to immediately under the gate electrode and diffuse an end portion of the second pillar region on a side of a second main surface to immediately under the first pillar region, the second main surface facing the first main surface; and
(h) implanting ions from the side of the first main surface to form a base region of the second conductivity type in a surface layer of the carrier stored region,
wherein wp3>wp2 and wp1>wp2 hold, where wp1 denotes a width of an upper end of the second pillar region that is an end portion on the side of the first main surface, wp2 denotes a width of the second pillar region at a same position as a lower end of the first pillar region, and wp3 denotes a width of a lower end of the second pillar region.

13. A method of manufacturing a semiconductor device, the method comprising:
(a) preparing a semiconductor wafer in which a bottom epitaxial layer of a first conductivity type is formed on a semiconductor substrate and a top epitaxial layer of the first conductivity type is formed on a surface layer of the bottom epitaxial layer;
(b) forming a second-pillar-region trench groove to penetrate the top epitaxial layer and reach the bottom epitaxial layer, and forming the top epitaxial layer excluding the second-pillar-region trench groove as a first pillar region;
(c) subjecting the second-pillar-region trench groove to an embedded epitaxial growth using a material doped with impurities of a second conductivity type to form a second pillar region;
(d) planarizing a first main surface to expose the first pillar region and the second pillar region in the first main surface, the first main surface being a surface of the semiconductor wafer on a side of the top epitaxial layer;
(e) implanting ions from a side of the first main surface to form a carrier stored region of the first conductivity type in a surface layer of the first pillar region and the second pillar region;
(f) implanting ions from the side of the first main surface to form a base region of the second conductivity type in a surface layer of the carrier stored region;
(g) performing a thermal diffusion process to diffuse the carrier stored region and the base region and to diffuse an end portion of the second pillar region on a side of a second main surface to immediately under the first pillar region, the second main surface facing the first main surface; and
(h) forming a gate trench groove to penetrate the base region and reach the carrier stored region, forming a gate insulating film on an inner wall of the gate trench groove, and forming a gate electrode to embed the gate trench groove,
wherein wp3>wp2 and wp1>wp2 hold, where wp1 denotes a width of an upper end of the second pillar region that is an end portion on the side of the first main surface, wp2 denotes a width of the second pillar region at a same position as a lower end of the first pillar region, and wp3 denotes a width of a lower end of the second pillar region.

14. The method according to claim 12, further comprising the steps of:
(i) completely removing the semiconductor substrate from the side of the second main surface to expose the bottom epitaxial layer;
(j) implanting ions from the side of the second main surface to form a buffer layer of the first conductivity type in a surface layer of the bottom epitaxial layer;
(k) implanting ions from the side of the second main surface to form a collector layer of the second conductivity type in a surface layer of the buffer layer; and
(l) activating the buffer layer and the collector layer.

15. The method according to claim 12,
wherein the semiconductor substrate is a substrate doped with impurities of the first conductivity type, the substrate being formed in a Czochralski (CZ) method, a magnetic field applied Czochralski (MCZ) method, or a floating zone (FZ) method.

16. The method according to claim 13, further comprising the steps of:
(i) completely removing the semiconductor substrate from the side of the second main surface to expose the bottom epitaxial layer;
(j) implanting ions from the side of the second main surface to form a buffer layer of the first conductivity type in a surface layer of the bottom epitaxial layer;
(k) implanting ions from the side of the second main surface to form a collector layer of the second conductivity type in a surface layer of the buffer layer; and
(l) activating the buffer layer and the collector layer.

17. The method according to claim 13,
wherein the semiconductor substrate is a substrate doped with impurities of the first conductivity type, the substrate being formed in a Czochralski (CZ) method, a magnetic field applied Czochralski (MCZ) method, or a floating zone (FZ) method.
